(19) United States
(12) Patent Application Publication
(10) Pub. No.: US 2026/0190650 A1
(43) Pub. Date: Jul. 2, 2026

(54) Display Device

(71) Applicant: LG Display Co., Ltd., Seoul (KR)

(72) Inventors: Wontae Park, Paju-si (KR); GiSang Hong, Paju-si (KR); Chaeeun Song, Paju-si (KR)

(21) Appl. No.: 19/432,766

(22) Filed: Dec. 24, 2025

(30) Foreign Application Priority Data
Dec. 30, 2024 (KR) 10-2024-0201204

(51) Int. Cl. H10K 59/122; H10K 59/131; H10K 59/80

(52) U.S. Cl. CPC H10K 59/122; H10K 59/131; H10K 59/8792

(57) ABSTRACT

The present disclosure provides to a display device comprising a substrate including a display area including subpixels and a non-display area surrounding the display area, a first line disposed on the substrate and extending in a first direction, a planarization layer disposed on the first line, a light emitting element including a first electrode disposed on the planarization layer, an intermediate layer disposed on the first electrode, and a second electrode disposed on the intermediate layer, a bank including an open area for exposing at least a portion of the first electrode, and a first line disconnection area located in the non-display area, a portion of the first line being disconnected in the first line disconnection area, the substrate and the bank being disposed to contact each other in the first line disconnection area, and is capable of improving visibility.

### CROSS REFERENCE TO RELATED APPLICATION

This application claims priority under 35 U.S.C. §119(a) to the Republic of Korea Patent Application No. 10-2024-0201204, filed on December 30, 2024, the contents of which are hereby expressly incorporated by reference into the present application.

### TECHNICAL FIELD

The present disclosure relates to electronic devices, and more specifically, to display devices.

### BACKGROUND

In today's information society, display devices for presenting images or visual information to users are increasingly important. The need for such display devices has caused display technology to be rapidly developed, and various types or usages of display devices have been developed. In addition, as display devices are becoming thinner and lighter, usages of the display devices are increasingly expanding, and displays are widely being applied in various fields of devices, apparatuses, and systems.

Display devices are widely used not only as televisions or monitors, but as display screens for notebook computers, tablet computers, smart phones, portable display devices, portable information devices, and the like.

Display devices may be classified into reflective display devices and emissive display devices. A reflective display device can display images or information by reflecting natural light or light from external lighting device outside of the display device onto the display device. An emissive display device can display images or information by using light generated by an embedded light emitting element or lighting source disposed into the display device.

### SUMMARY

One or more aspects of the present disclosure may provide a display device that includes a structure where a black bank is disposed to contact a substrate and is capable of improving a light shielding ratio.

One or more aspects of the present disclosure may provide a display device that includes a structure where internal and external light is blocked in a non-display area and is capable of improving visibility.

One or more aspects of the present disclosure may provide a display device that includes a structure where over-etching of metal layers can be prevented and a distance between lines can be minimized and is capable of presenting a high resolution.

One or more aspects of the present disclosure may provide a display device that includes a structure where metal layers located in different layers are simultaneously removed and is capable of enabling process optimization.

One or more aspects of the present disclosure may provide a display device that includes a structure where a distance between lines can be minimized and is capable of presenting a high resolution and being driven with low power.

One or more aspects of the present disclosure may provide a display device that includes a structure where a vertical thickness of a bank located in a first line disconnection area is greater than a vertical thickness of a bank located above an another first line.

Aspects, examples, and embodiments provided in the present disclosure are not limited to the foregoing description, and additional aspects, examples, and embodiments provided in the present disclosure will become apparent to those skilled in the art from the following description.

According to one or more example embodiments of the present disclosure, a display device can be provided that includes a substrate including a display area including subpixels and a non-display area surrounding the display area, a first line disposed on the substrate and extending in a first direction, a planarization layer disposed on the first line, a light emitting element including a first electrode disposed on the planarization layer, an intermediate layer disposed on the first electrode, and a second electrode disposed on the intermediate layer, a bank including an open area for exposing at least a portion of the first electrode, and a first line disconnection area located in the non-display area, a portion of the first line being disconnected in the first line disconnection area. In one or more aspects, the substrate and the bank may be disposed to contact each other in the first line disconnection area.

According to one or more aspects of the present disclosure, a display device may be provided that is capable of improving a light shielding ratio by including a structure where a black bank is disposed to contact a substrate.

According to one or more aspects of the present disclosure, a display device may be provided that is capable of improving visibility by including a structure where internal and external light is blocked in a non-display area.

According to one or more aspects of the present disclosure, a display device may be provided that is capable of presenting a high resolution by including a structure where over-etching of metal layers can be prevented and a distance between lines can be minimized.

According to one or more aspects of the present disclosure, a display device may be provided that is capable of enabling process optimization by including a structure where metal layers located in different layers are simultaneously removed.

According to one or more aspects of the present disclosure, a display device may be provided that is capable of presenting a high resolution and being driven with low power by including a structure where a distance between lines can be minimized.

According to the one or more aspects described herein, a display device may be provided that comprises a substrate comprising a display area comprising subpixels and a non-display area, a first line disposed on the substrate and extending in a first direction, an insulating layer disposed on the first line, a light emitting element comprising a first electrode disposed on the insulating layer, an intermediate layer disposed on the first electrode, and a second electrode disposed on the intermediate layer, a bank comprising an open area for exposing at least a portion of the first electrode, and a first line disconnection area located in the non-display area. In one or more aspects, in the display device, a first portion of the first line is disconnected from a second portion of the first line in the first line disconnection area. In one or more aspects, in the display device, a vertical thickness of the bank located in the first line disconnection area is greater than a vertical thickness of the bank located above an another first line.

Effects or advantages from aspects, examples, and embodiments described herein are not limited thereto, and additional effects or advantages will become apparent to those skilled in the art from the following description.

### BRIEF DESCRIPTION OF THE DRAWINGS

The accompanying drawings, which are included to provide a further understanding of the disclosure and are incorporated in and constitute a portion of the disclosure, illustrate aspects of the disclosure and together with the description serve to explain principles of the disclosure. It should be therefore understood that aspects, examples, and embodiments described herein are not limited to the illustrations of the accompanying drawings. In the drawings:

FIG. 1 illustrates an example system configuration of a display device according to aspects of the present disclosure.

FIG. 2 is a cross-sectional view of an example subpixel area defined in a display panel according to aspects of the present disclosure.

FIG. 3 is an example of an enlarged view of area A of FIG. 1.

FIG. 4 is an example of a cross-sectional view of the display panel according to aspects of the present disclosure.

FIG. 5 is an example of a cross-sectional view illustrating the structure of a normal gate electrode and the structure of a gate electrode in FIG. 4.

FIG. 6 is an example of a cross-sectional view of a data line in FIG. 4.

FIG. 7 illustrates an example of a process for manufacturing the display panel according to aspects of the present disclosure.

FIG. 8 illustrates an example of a process for manufacturing the display panel according to aspects of the present disclosure.

FIG. 9 illustrates an example of a process for manufacturing the display panel according to aspects of the present disclosure.

FIG. 10 illustrates an example of a process for manufacturing the display panel according to aspects of the present disclosure.

FIG. 11 illustrates an example of a process for manufacturing the display panel according to aspects of the present disclosure.

FIG. 12 illustrates an example of a process for manufacturing the display panel according to aspects of the present disclosure.

FIG. 13 illustrates an example of a process for manufacturing the display panel according to aspects of the present disclosure.

FIG. 14 illustrates an example of a process for manufacturing the display panel according to aspects of the present disclosure.

### DETAILED DESCRIPTION

Reference will now be made in detail to example embodiments of the present disclosure, examples or aspects of which may be illustrated in the accompanying drawings. In the following description, the structures, implementations, methods, and operations described herein are not limited to the specific examples, aspects, and embodiments set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products. Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents. In the following description, where the detailed description of the relevant known function or configuration may unnecessarily obscure aspects of the present disclosure, a detailed description of such known function or configuration may be omitted. The shapes, sizes, ratios, angles, numbers, and the like, which are illustrated in the drawings to describe various example embodiments of the present disclosure, are merely given by way of example. Therefore, the present disclosure is not limited to the illustrations in the drawings. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Although the terms “first,” “second,” A, B, (a), (b), and the like may be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element "is connected or coupled to", “contacts”, “ overlaps with”, or the like a second element, it should be interpreted that, not only can the first element “be directly connected or coupled to”, “directly contact”, or “directly overlap with” the second element, but a third element can also be "interposed" between the first and second elements, or the first and second elements can "be connected or coupled to", “contact”, “overlap with”, or the like each other via a fourth element. Here, the second element may be included in at least one of two or more elements that "are connected or coupled to", “contact”, “overlap with”, or the like each other.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes etc. are mentioned, it should be considered that numerical values for an elements or features, or corresponding information (e.g., level, range, and the like) include a tolerance or error range that may be caused by various factors (e.g., process factors, internal or external impact, noise, and the like) even when a relevant description is not specified. Further, the term “may” fully encompasses all the meanings of the term “can”.

In the following description, various example aspects of the present disclosure are described in detail with reference to the accompanying drawings. With respect to reference numerals to elements of each of the drawings, the same elements may be illustrated in other drawings, and similar reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, aspects of the present disclosure are not limited to a scale, dimension, size, and thickness illustrated in the drawings.

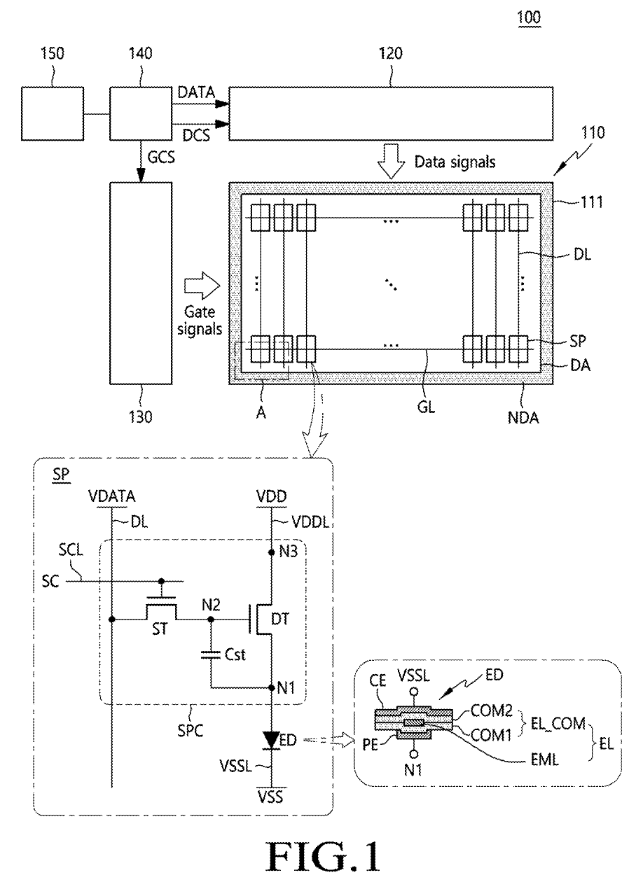

FIG. 1 illustrates an example of a system configuration of a display device 100 according to aspects of the present disclosure.

Referring to FIG. 1, in one or more example embodiments, the display device 100 may include a display panel 110 and at least one display driving circuit, as elements for display images. The at least one display driving circuit may be a circuit for driving the display panel 110, and include a data driving circuit 120, a gate driving circuit 130, a controller 140, and other circuit components.

The display panel 110 may include a substrate 111 and a plurality of subpixels SP disposed on the substrate 111.

The substrate 111 may include a display area DA allowing an image to be displayed and a non-display area NDA around an outer edge of the display area DA.

The display area DA may also be referred to as an active area, and a plurality of subpixels SP for displaying images may be disposed in the display area DA. The non-display area NDA may also be referred to as a non-active area and include a pad area PA.

In one or more aspects, the display panel 110 may be configured to have a very small non-display area NDA. The non-display area NDA may be also referred to as a “bezel” or “bezel area.” For example, the non-display area NDA may include a first non-display area located outside of the display area DA in a first direction, a second non-display area located outside of the display area DA in a second direction, a third non-display area located outside of the display area DA in a direction opposite to the first direction, and a fourth non-display area located outside of the display area DA in a direction opposite to the second direction.

The first non-display area among the first to fourth non-display areas may include a pad area to which one or more driving circuits are connected or bonded. Among the first to fourth non-display areas, the second to fourth non-display areas may have a very small size compared to the first non-display area.

In one or more aspects, a boundary area may be defined between the display area DA and the non-display area NDA. For example, the boundary area may be bent at a certain angle to the display area DA, and thereby, at least a portion of the non-display area NDA may be located under the display area DA. In this implementation, when a user views the display device 100 in front thereof, all or most of the non-display area NDA may be invisible to the user. For example, the first non-display area may include a bending area. As the bending area is bent, the first non-display area may be invisible in front of the display device 100.

Several types of signal lines for driving a plurality of subpixels SP may be disposed on the substrate 111 of the display panel 110.

In one or more aspects, the display device 100 herein may be a liquid crystal display device, or the like, or a self-emissive display device in which light is emitted from the display panel 110 itself. In an example where the display device 100 is the self-emissive display device, each of the plurality of subpixels SP may include a light emitting element.

For example, the display device 100 according to aspects of the present disclosure may be an organic light emitting display device in which light emitting elements are implemented using organic light emitting diodes (OLED). In another example, the display device 100 according to aspects of the present disclosure may be an inorganic light emitting display device in which light emitting elements are implemented using inorganic material-based light emitting diodes. In another example, the display apparatus 100 according to aspects of the present disclosure may be a quantum dot display apparatus in which the light emitting element is implemented using quantum dots, which are self-emission semiconductor crystals. But aspects of the present disclosure are not limited thereto.

The structure of each or at least one of a plurality of subpixels SP included in the display device 100 may depend on types of the display device 100. For example, when the display device 100 is a self-emissive display device including self-emissive subpixels SP, each subpixel SP may include a self-emissive light emitting element, one or more transistors, and one or more capacitors.

Referring to FIG. 1, each or at least one of the plurality of subpixels SP disposed in the display panel 110 may include a light emitting element ED and a subpixel circuit SPC configured to drive the light emitting element ED.

Referring to FIG. 1, the subpixel circuit SPC may include a plurality of transistors and at least one capacitor for driving the light emitting element ED. The subpixel circuit SPC can drive the light emitting element ED by supplying a driving current to the light emitting element ED at a predetermined timing. The light emitting element ED can emit light by being driven by the driving current.

The plurality of transistors may include a driving transistor DT configured to drive the light emitting element ED and a scan transistor ST configured to be turned on or off by a scan signal SC.

The driving transistor DT can supply a driving current to the light emitting element ED.

The scan transistor ST may be configured to control an electrical state of a corresponding node in the subpixel circuit SPC or to control the state or operation of the driving transistor DT.

The at least one capacitor may include a storage capacitor Cst configured to maintain a voltage at a constant level during a display frame or a period of the display frame.

To drive at least one subpixel SP, at least one data signal VDATA, which is an image signal, and at least one scan signal SC, which is a gate signal, may be applied to the at least one subpixel SP. Further, to drive one or more subpixels SP, at least one common driving voltage including a first common driving voltage VDD and a second common driving voltage VSS may be applied to the one or more subpixels SP.

The light emitting element ED may include a first electrode PE, an intermediate layer EL, and a second electrode CE. The intermediate layer EL may be disposed between the first electrode PE and the second electrode CE. The first electrode PE may be a pixel electrode PE, and the second electrode CE may be a common electrode CE.

For example, the pixel electrode PE may be an electrode disposed in each subpixel SP, and the common electrode CE may be an electrode disposed commonly in all or some of a plurality of subpixels SP. For example, the pixel electrode PE may be an anode electrode, and the common electrode CE may be a cathode electrode. In another example, the pixel electrode PE may be a cathode electrode, and the common electrode CE may be an anode electrode. Hereinafter, for convenience of explanation, discussions may be provided based on examples where the pixel electrode PE is an anode electrode, and the common electrode CE is a cathode electrode.

In an example where the light emitting element ED is an organic light emitting diode, the intermediate layer EL may include an emission layer EML, a first common intermediate layer COM1 between the pixel electrode PE and the emission layer EML, and a second common intermediate layer COM2 between the emission layer EML and the common electrode CE. A layer including the first common intermediate layer COM1 and the second common intermediate layer COM2 may be referred to as a common intermediate layer EL_COM.

For example, the emission layer EML may be disposed for each subpixel SP, and the common intermediate layer EL_COM may be commonly disposed across all or some of a plurality of subpixels SP.

For example, the emission layer EML may be disposed for each light emitting area, and the common intermediate layer EL_COM may be commonly disposed across a plurality of light emitting areas and a non-light emitting area.

For example, the emission layer EML and the common intermediate layer EL_COM may be commonly disposed across all or some of a plurality of subpixels SP.

For example, the emission layer EML and the common intermediate layer EL_COM may be commonly disposed across a plurality of light emitting areas and a non-light emitting area.

For example, the first common intermediate layer COM1 may include a hole injection layer (HIL), a hole transfer layer (HTL), and the like. The second common intermediate layer COM2 may include an electron transport layer (ETL), an electron injection layer (EIL), and the like.

The hole injection layer can inject holes from the pixel electrode PE to the hole transport layer, the hole transport layer can transport holes to the emission layer EML. The electron injection layer can inject electrons from the common electrode CE to the electron transport layer, and the electron transport layer can transport electrons to the emission layer EML.

For example, the common electrode CE may be electrically connected to a second common driving voltage line VSSL. A second common driving voltage VSS may be applied to the common electrode CE through the second common driving voltage line VSSL. The pixel electrode PE may be electrically connected directly or indirectly (via another transistor) to a first node N1 of the corresponding driving transistor DT of each subpixel SP. Herein, the second common driving voltage VSS may also be referred to as a “base voltage”, and the second common driving voltage line VSSL may also be referred to as a “low power supply voltage line”, a “low voltage line”, or a “base voltage line.

Each light emitting element ED may be configured by overlapping of a pixel electrode PE, an emission layer EML in an intermediate layer EL, and a common electrode CE. A respective light emitting area may be formed by each light emitting element ED. For example, a respective light emitting area of each light emitting element ED may include an area where a pixel electrode PE, an emission layer EML in an intermediate layer EL, and a common electrode CE overlap with each other

In one or more aspects, each or at least one of a plurality of light emitting elements ED included in the display panel 110 to the display device 100 may be an organic light emitting diode (OLED), an inorganic light emitting diode (LED), a quantum dot (QD) light emitting element, a micro light emitting diode, a mini light emitting diode, or the like, but aspects of the present disclosure are not limited thereto. In the example where each light emitting element ED is an organic light emitting diode (OLED), the intermediate layer EL of a corresponding light emitting element ED may be a layer including an organic material.

The driving transistor DT may be a transistor configured to supply a driving current to the light emitting element ED. The driving transistor DT may be connected between a first common driving voltage line VDDL and the light emitting element ED.

The driving transistor DT may include a first node N1, a second node N2, and a third node N3. The first node N1 may be electrically connected to the light emitting element ED. A data signal VDATA may be applied to the second node N2. A first common driving voltage VDD delivered through the first common driving voltage line VDDL may be applied to the third node N3.

In the driving transistor DT, the second node N2 may be a gate node, the first node N1 may be a source node or a drain node, and the third node N3 may be the drain node or the source node. Hereinafter, for merely convenience of explanation, discussions may be provided based on examples where the first, second, and third nodes (N1, N2, and N3) of the driving transistor DT are source, gate, and drain nodes, respectively. However, aspects of the present disclosure are not limited thereto.

The scan transistor ST included in the subpixel circuit SPC illustrated in FIG. 1 may be a switching transistor for transferring a data signal VDATA, which is an image signal, to the second node N2, which is the gate node of the driving transistor DT.

The scan transistor ST can be turned on or turned off by a scan signal SC, which is a type of gate signal, applied through a scan line SCL, which is a type of gate line GL, and control an electrical connection between the second node N2 of the driving transistor DT and a data line DL. The drain electrode or source electrode of the scan transistor ST may be electrically connected to the data line DL. The source electrode or drain electrode of the scan transistor ST may be electrically connected to the second node N2 of the driving transistor DT. The gate electrode of the scan transistor ST may be electrically connected to the scan line SCL.

The storage capacitor Cst may be electrically connected between the first node N1 and the second node N2 of the driving transistor DT. The storage capacitor Cst may include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The storage capacitor Cst may be an external capacitor intentionally designed to be located outside of the driving transistor DT, and therefore, be different from an internal capacitor such as a parasitic capacitor (e.g., a Cgs, a Cgd) that may be formed between the first node N1 and the second node N2 of the driving transistor DT.

Each of the driving transistor DT and the scan transistor ST may be an n-type transistor or a p-type transistor.

The display panel 110 may have a top emission structure or a bottom emission structure.

In an example where the display panel 110 has the top emission structure, at least a portion of the subpixel circuit SPC may overlap with at least a portion of the light emitting element ED in the vertical direction. In this configuration, the area or size of a corresponding light emitting area can increase, and a corresponding aperture ratio can increase.

In an example where the display panel 110 has the bottom emission structure, the subpixel circuit SPC may not overlap with the light emitting element ED in the vertical direction.

The subpixel circuit SPC may have a 2T(Transistor)1C(Capacitor) structure including two transistors (DT and ST) and one capacitor (Cst) as illustrated in FIG. 1. In one or more aspects, the subpixel circuit SPC may further include one or more transistors or one or more capacitors in the 2T1C structure.

For example, the subpixel circuit SPC may have an 8T1C structure including 8 transistors and 1 capacitor. In another example, the subpixel circuit SPC may have a 6T2C structure including 6 transistors and 2 capacitor. In another example, the subpixel circuit SPC may have a 7T1C structure including 7 transistors and 1 capacitor. However, aspects of the present disclosure are not limited to such specific structures.

The types and number of signals supplied to a subpixel SP, and/or the types and number of lines connected to the subpixel SP may vary depending on a structure of a corresponding subpixel circuit SPC. Further, the types and number of common driving voltages supplied to a subpixel SP may vary depending on a structure of a corresponding subpixel circuit SPC.

The several types of signal lines may include, for example, a plurality of data lines DL for carrying data signals (which may be referred to as data voltages or image signals), a plurality of gate lines GL for carrying gate signals (which may be referred to as scan signals), and the like.

For example, the plurality of data lines DL and the plurality of gate lines GL may intersect one another. Each of the plurality of data lines DL may be configured to extend in a first direction, and each of the plurality of gate lines GL may be configured to extend in a second direction. For example, the first direction may be the column direction, and the second direction may be the row direction. In another example, the first direction may be the row direction, and the second direction may be the column direction. Hereinafter, for merely convenience of explanation, discussions are provided based on examples where the first direction is the column direction, and the second direction is the row direction. Hereinafter, for convenience of explanation, discussions may be provided based on examples where each of a plurality of data lines DL is disposed in the column direction, and each of a plurality of gate lines GL is disposed in the row direction, but aspects of the present disclosure are limited thereto.

The data driving circuit 120 may be a circuit for driving a plurality of data lines DL and can output data signals to the plurality of data lines DL.

The data driving circuit 120 can receive image data DATA in digital form from the controller 140, convert the received image data DATA into data signals in analog form, and output the resulting data signals to the plurality of data lines DL.

In one or more aspects, the data driving circuit 120 may be connected to the display panel 110 by a tape-automated-bonding (TAB) technology, or connected to a conductive pad such as a bonding pad of the display panel 110 by a chip-on-glass (COG) technology or a chip-on-panel (COP) technology, or connected to the display panel 110 by a chip-on-film (COF) technology. However, aspects of the present disclosure are not limited thereto.

In one or more aspects, the data driving circuit 120 may be disposed in, and/or electrically connected to, but not limited to, only one side or edge (e.g., an upper portion or a lower portion) of the display panel 110. In one or more aspects, the data driving circuit 120 may be disposed in, and/or electrically connected to, but not limited to, two sides or edges (e.g., an upper portion and a lower portion) of the display panel 110 or at least two of four sides or edges (e.g., the upper portion, the lower portion, a left portion, and a right portion) of the display panel 110 according to driving schemes, panel design schemes, or the like.

The data driving circuit 120 may be connected to an area outward from the display area DA of the display panel 110 or be disposed in the display area DA of the display panel 110.

The gate driving circuit 130 may be a circuit configured to drive a plurality of gate lines GL and can output gate signals to the plurality of gate lines GL.

The gate driving circuit 130 can receive several types of gate driving control signals GCS, and further, receive a first gate voltage corresponding to a turn-on level voltage and a second gate voltage corresponding to a turn-off level voltage. Thereby, the gate driving circuit 130 can generate gate signals and supply the generated gate signals to the plurality of gate lines GL.

In one or more aspects, the gate driving circuit 130 included in the display device 100 may be embedded into the display panel 110 by a gate-in-panel (GIP) technique. In an example where the gate driving circuit 130 is implemented by the gate-in-panel (GIP) technique, the gate driving circuit 130 may be disposed on the substrate 111 of the display panel 110 during the manufacturing process of the display panel 110 or display device 100.

In one or more aspects, the gate driving circuit 130 may be disposed in the non-display area NDA of the display panel 110.

In one or more aspects, the gate driving circuit 130 may be disposed in the display area DA of the display panel 110. In this implementation, for example, the gate driving circuit 130 may be disposed in, and/or electrically connected to, but not limited to, a first area (e.g., a left area or a right area) of the display area DA of the display panel 110. In one or more aspects, the gate driving circuit 130 may be disposed in, and/or electrically connected to, but not limited to, a first partial area (e.g., a left portion or a right portion) in the display area DA, and a second partial area (e.g., the right portion or the left portion) in the display area DA.

Herein, the gate driving circuit 130 embedded in the display panel 110 by the gate-in-panel (GIP) technique may also be referred to as a “gate-in-panel circuit.”

The controller 140 may be a device configured to control the data driving circuit 120 and the gate driving circuit 130, and can control driving timing for the plurality of data lines DL and driving timing for the plurality of gate lines GL.

The controller 140 can supply a data control signal DCS to the data driving circuit 120 to control the data driving circuit 120 and supply a gate control signal GCS to the gate driving circuit 130 to control the gate driving circuit 130.

The controller 140 can receive image data input from a host system 150 and supply image data DATA readable by the data driving circuit 120 based on the input image data to the data driving circuit 120.

The controller 140 may be implemented in a separate component from the data driving circuit 120, or integrated with the data driving circuit 120, so that the controller 140 and the data driving circuit 120 can be implemented in a single integrated circuit.

The controller 140 may be a timing controller used in the typical display technology or a control apparatus/device capable of additionally performing other control functionalities in addition to the typical function of the timing controller. In one or more embodiments, the controller 140 may be one or more other control circuits different from the timing controller, or a circuit or component in the control apparatus/device. The controller 140 may be implemented using various circuits or electronic components such as an integrated circuit (IC), a field programmable gate array (FPGA), an application specific integrated circuit (ASIC), a processor, and/or the like. However, aspects of the present disclosure are not limited thereto.

The controller 140 may be mounted on a printed circuit board, a flexible printed circuit, or the like, and may be electrically connected to the data driving circuit 120 and the gate driving circuit 130 through the printed circuit board, the flexible printed circuit, and/or the like.

The controller 140 can transmit signals to, and receive signals from, the data driving circuit 120 via one or more predetermined interfaces. For example, such interfaces may include a low voltage differential signaling (LVDS) interface, an embedded clock point-point interface (EPI), a serial peripheral interface (SPI), and the like. However, aspects of the present disclosure are not limited thereto.

In one or more aspects, to provide a touch sensing function, as well as an image display function, the display device 100 may include a touch sensor, and a touch sensing circuit configured to sense the touch sensor and detect whether a touch is applied by an object such as a finger, a pen, or the like, or a location of the touch (or touch coordinates).

The touch sensing circuit may include a touch driving circuit configured to drive and sense the touch sensor and generate and output touch sensing data, and a touch controller configured to detect whether a touch is applied, or a location of the touch (or touch coordinates) based on the touch sensing data.

The touch sensor may include a plurality of touch electrodes. The touch sensor may further include a plurality of touch lines for electrically connecting the plurality of touch electrodes to the touch driving circuit.

The touch sensor may be disposed outside of the display panel 110 in the form of a touch panel or may be disposed inside of the display panel 110. The touch sensor disposed outside of the display panel 110 may be referred to as an add-on type touch sensor. In the example where the add-on type of touch sensor is disposed in the display device 100, the touch panel and the display panel 110 may be separately manufactured and combined in an assembly process. The add-on type of touch panel may include a touch panel substrate and a plurality of touch electrodes disposed on the touch panel substrate.

In the example where the touch sensor is disposed inside of the display panel 110, the touch sensor may be formed on the substrate along with signal lines and electrodes related to display driving during the manufacturing process of the display panel 110.

The touch driving circuit can supply a touch driving signal to at least one of a plurality of touch electrodes and generate touch sensing data by sensing at least one of the plurality of touch electrodes.

The touch sensing circuit can perform touch sensing by a self-capacitance sensing technique or a mutual-capacitance sensing technique.

In the example where the touch sensing circuit performs touch sensing by the self-capacitance sensing technique, the touch sensing circuit can perform touch sensing based on capacitance between each touch electrode and a touch object (e.g., a finger, a pen, and the like). According to the self-capacitance sensing technique, each of a plurality of touch electrodes can serve as both a driving touch electrode and a sensing touch electrode. The touch driving circuit may drive all, or one or more, of a plurality of touch electrodes and sense all, or one or more, of the plurality of touch electrodes.

In the example where the touch sensing circuit performs touch sensing by the mutual-capacitance sensing technique, the touch sensing circuit can perform touch sensing based on a capacitance between touch electrodes. According to the mutual-capacitance sensing technique, a plurality of touch electrodes may be divided into driving touch electrodes and sensing touch electrodes. The touch driving circuit can drive the driving touch electrodes and sense the sensing touch electrodes.

In one or more aspects, the touch driving circuit and touch controller included in the touch sensing circuit may be implemented in separate devices or in a single device. In one or more aspects, the touch driving circuit and the data driving circuit may be implemented in separate devices or in a single device.

The display device 100 may further include a power supply circuit for supplying several types of power to the display driving circuit and/or the touch sensing circuit.

In one or more aspects, the display device 100 may be a mobile terminal such as a smart phone, a tablet, or the like, or a monitor, a television (TV), or the like. Further, the display device 100 may be configured with various types, sizes, and shapes to display information or images. For example, the display device 100 may be applied to mobile devices, video phones, smart watches, watch phones, wearable apparatuses, foldable apparatuses, rollable apparatuses, bendable apparatuses, flexible apparatuses, stretchable apparatuses, curved apparatuses, sliding apparatuses, variable apparatuses, electronic notebooks, e-books, portable multimedia players (PMP), personal digital assistants (PDA), MP3 players, mobile medical apparatuses, desktop PCs, laptop PCs, netbook computers, workstations, navigation apparatuses, car navigation apparatuses, vehicle display apparatuses, vehicle apparatuses, theater apparatuses, theater display apparatuses, televisions, wallpaper apparatuses, signage apparatuses, game apparatuses, notebook computers, monitors, cameras, camcorders, and home appliances, and the like.

In one or more aspects, the display device 100 may further include an electronic device such as a camera (e.g., an image sensor), a sensor capable of detecting an object, ambient light, and the like. For example, the sensor may be a sensor capable of detecting an object or a human body by receiving light such as infrared light, ultrasonic light, ultraviolet light or the like.

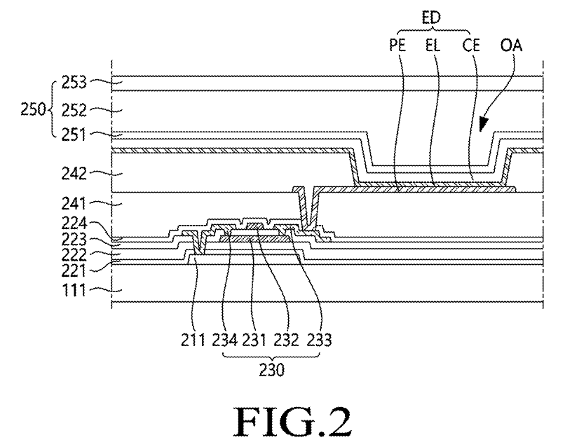

FIG. 2 is a cross-sectional view of an example subpixel area defined in the display panel 110 according to aspects of the present disclosure. In discussions that follow for the configuration of FIG. 2, discussions for features and configurations equal, substantially equal, or similar to the features and configurations described with reference to FIG. 1 are omitted or briefly described for conciseness.

Referring to FIG. 2, in one or more example embodiments, the display panel 110 may include at least one transistor 230 disposed on a substrate 111 and a light emitting element ED electrically connected to the at least one transistor 230.

The transistor 230 may include an active layer 231, a gate electrode 232, a first electrode pattern 233, and a second electrode pattern 234. The light emitting element ED may include a first electrode PE, an intermediate layer EL, and a second electrode CE.

The substrate 111 may include a single layer or a multilayer. The substrate 111 may include a glass or plastic material. When the substrate 111 includes a multilayer, the substrate 111 may include a first substrate, a substrate intermediate layer, and a second substrate. The substrate intermediate layer may be located between the first substrate and the second substrate. For example, each of the first substrate and the second substrate may be a polyimide (PI) layer. The substrate intermediate layer may be an inorganic insulating layer. When electric charges are stored on the first substrate which is a polyimide (PI) layer, the substrate intermediate layer can block the charges from affecting transistors on the second substrate through the second substrate, which is a polyimide (PI) layer.

The substrate intermediate layer can block moisture from penetrating upwardly through the first substrate. For example, the substrate intermediate layer may be in the form of a single layer of silicon nitride (SiNₓ) or silicon oxide (SiOₓ), a multilayer of silicon nitride (SiNₓ), silicon oxide (SiOₓ), and the like, or a double layer of silicon oxide (SiOₓ) and silicon nitride (SiNₓ). However, aspects of the present disclosure are not limited thereto.

A light shielding layer 211 may be disposed on the substrate 111.

The light shielding layer 211 may be disposed to be overlapped with at least a portion of the active layer 231 of the transistor 230. For example, the light shielding layer 211 may be disposed to be overlapped with a channel region of the active layer 231. When the channel region of the active layer 231 is exposed to light, the channel characteristics of the active layer 231 may be changed, and thereby, the operating characteristics of the transistor 230 may also be changed. To address this issue, as the light shielding layer 211 is disposed to be overlapped with the channel region of the transistor 230, the channel region can be prevented from being exposed to light. Accordingly, the operating characteristics of the transistor 230 can be performed stably.

In one or more aspects, the light shielding layer 211 may be used as a data line DL or a first common driving voltage line VDDL. In this configuration, the light shielding layer 211 may be connected to the first electrode pattern 233 of the transistor 230.

The light shielding layer 211 may have a single-layer structure, but aspects of the present disclosure are not limited thereto. For example, the light shielding layer 211 may include copper (Cu), aluminum (Al), molybdenum (Mo), titanium (Ti), or an alloy material thereof (e.g., MoTi). For example, the light shielding layer 211 may include a low-reflective material such as molybdenum-titanium oxide (MoTiOₓ), molybdenum-tantalum oxide (MoTaOₓ), tungsten oxide (WOₓ), molybdenum-copper oxide (MoCuOₓ), and molybdenum-chromium oxide (MoCrOₓ).

FIG. 2 illustrates the light shielding layer 211 with a single-layer structure, but aspects of the present disclosure are not limited thereto. For example, the light shielding layer 211 may have a multilayer structure including two or more layers. For example, the light shielding layer 211 may include a first layer and a second layer, which are sequentially stacked. The first layer located on the substrate 111 may be an oxide metal layer, and the second layer located on the first layer may include a metal material having low surface resistance. For example, the first layer may include a material such as molybdenum-titanium oxide (MoTiOₓ), molybdenum-tantalum oxide (MoTaOₓ), tungsten oxide (WOₓ), molybdenum-copper oxide (MoCuOₓ), and molybdenum-chromium oxide (MoCrOₓ). The second layer may include copper (Cu), aluminum (Al), molybdenum (Mo), titanium (Ti), or an alloy material thereof (e.g., MoTi).

A first insulating layer 222 may be disposed on the light shielding layer 211. The first insulating layer 222 may be a buffer layer. The first insulating layer 222 may include an inorganic insulating material such as silicon oxide (SiOₓ), silicon nitride (SiNₓ), or silicon oxynitride (SiOₓN_{y}), but aspects of the present disclosure are not limited thereto.

FIG. 2 illustrates the first insulating layer 222 with a single-layer structure, but aspects of the present disclosure are not limited thereto. For example, the first insulating layer 222 may have a multilayer structure. When the first insulating layer 222 has a multilayer structure, the first insulating layer 222 may have a structure in which at least two inorganic insulating materials each including an inorganic material such as silicon oxide (SiOₓ), silicon nitride (SiNₓ), or silicon oxynitride (SiOₓN_{y}) are alternately stacked, but aspects of the present disclosure are not limited thereto.

In one or more aspects, a fourth insulating layer 221 may be disposed between the light shielding layer 211 and the first insulating layer 222. The fourth insulating layer 221 may be an interlayer insulating layer. The fourth insulating layer 221 may include an inorganic insulating material such as silicon oxide (SiOₓ), silicon nitride (SiNₓ), or silicon oxynitride (SiOₓN_{y}), but aspects of the present disclosure are not limited thereto.

FIG. 2 illustrates the fourth insulating layer 221 with a single-layer structure, but aspects of the present disclosure are not limited thereto. For example, the fourth insulating layer 221 may have a multilayer structure. When the fourth insulating layer 221 has a multilayer structure, the fourth insulating layer 221 may have a structure in which at least two inorganic insulating materials each including an inorganic material such as silicon oxide (SiOₓ), silicon nitride (SiNₓ), or silicon oxynitride (SiOₓN_{y}) are alternately stacked, but aspects of the present disclosure are not limited thereto.

The transistor 230 may be disposed on the first insulating layer 222. The transistor 230 may include the active layer 231, the gate electrode 232, the first electrode pattern 233, and the second electrode pattern 234.

The active layer 231 of the transistor 230 may be disposed on the first insulating layer 222.

The active layer 231 may be a semiconductor layer of various types. For example, the active layer 231 may include an oxide semiconductor, amorphous silicon, polysilicon, or low-temperature polysilicon (LTPS), but aspects of the present disclosure are not limited thereto.

FIG. 2 illustrates the active layer 231 with a single-layer structure, but aspects of the present disclosure are not limited thereto. For example, the active layer 231 may have a multilayer structure.

When the active layer 231 includes an oxide semiconductor material, an auxiliary electrode including a metal or a transparent electrode material may be disposed in the remaining area except for the channel area of the active layer 231.

A second insulating layer 223 may be disposed on the active layer 231. The second insulating layer 223 may be a gate insulating layer.

The second insulating layer 223 may include an inorganic insulating material such as silicon oxide (SiOₓ), silicon nitride (SiNₓ), or silicon oxynitride (SiOₓN_{y}), but aspects of the present disclosure are not limited thereto.

FIG. 2 illustrates a structure in which the second insulating layer 223 is disposed on a portion of the upper surface of the active layer 231, but aspects of the present disclosure are not limited thereto. For example, the second insulating layer 223 may be disposed to cover the upper surface of the active layer 231.

The gate electrode 232, the first electrode pattern 233, and the second electrode pattern 234 of the transistor 230 may be disposed on the second insulating layer 223.

The gate electrode 232 may include a conductive material. For example, the gate electrode 232 may include one of molybdenum (Mo), aluminum (Al), chromium (Cr), gold (Au), platinum (Pt), titanium (Ti), nickel (Ni), neodymium (Nd), palladium (Pd), silver (Ag), tungsten (W), or copper (Cu), or one or more alloys of two or more of molybdenum (Mo), aluminum (Al), chromium (Cr), gold (Au), platinum (Pt), titanium (Ti), nickel (Ni), neodymium (Nd), palladium (Pd), silver (Ag), tungsten (W), and/or copper (Cu), or may include a transparent conductive material. However, aspects of the present disclosure are not limited thereto.

Referring to FIG. 2, the second insulating layer 223 may be disposed in an area overlapped with the gate electrode 232. An area where the active layer 231 is overlapped with the gate electrode 232 may act as a channel region of the transistor 230. An area where the active layer 231 is not overlapped with the gate electrode 232 may be a conductivity-enabled region.

For example, the first electrode pattern 233 may be a source electrode, and the second electrode pattern 234 may be a drain electrode. In another example, the first electrode pattern 233 may be a drain electrode, and the second electrode pattern 234 may be a source electrode.

Each of the first electrode pattern 233 and the second electrode pattern 234 may include a conductive material. For example, each of the first electrode pattern 233 and the second electrode pattern 234 may include one of molybdenum (Mo), aluminum (Al), chromium (Cr), gold (Au), platinum (Pt), titanium (Ti), nickel (Ni), neodymium (Nd), palladium (Pd), silver (Ag), tungsten (W), or copper (Cu), or one or more alloys of two or more of molybdenum (Mo), aluminum (Al), chromium (Cr), gold (Au), platinum (Pt), titanium (Ti), nickel (Ni), neodymium (Nd), palladium (Pd), silver (Ag), tungsten (W), and/or copper (Cu), or may include a transparent conductive material. However, aspects of the present disclosure are not limited thereto.

The first electrode pattern 233 and the second electrode pattern 234 may be connected electrically and physically to portions of the conductivity-enabled region of the active layer 231 through contact holes of the second insulating layer 223, respectively.

The gate electrode 232, the first electrode pattern 233, and the second electrode pattern 234 may be disposed in the same layer and include the same material.

The second electrode pattern 234 may be electrically connected to a portion of the upper surface of the light shielding layer 211 through a contact hole (e.g., a first contact hole) of the first insulating layer 222. For example, the second electrode pattern 234 may be electrically connected to the light shielding layer 211 through the contact hole. The first contact hole may be formed by penetrating the fourth insulating layer 221, the first insulating layer 222, and the second insulating layer 223.

Referring to FIG. 2, in one or more aspects, the display device may include a capacitor 212.

The capacitor 212 may include a first capacitor electrode 212a, a second capacitor electrode 212b on the first capacitor electrode 212a.

The first capacitor electrode 212a may be a metal plate. For example, the first capacitor electrode 212a may be located in the same layer as the light shielding layer 211 and include the same material as the light shielding layer 211. The second capacitor electrode 212b may be located in the same layer as the active layer 231 and be another active layer in a conductivity-enabled state.

A third insulating layer 224 for insulating the transistor 230 may be disposed on the gate electrode 232, the first electrode pattern 233, and the second electrode pattern 234. The third insulating layer 224 may include an inorganic insulating material such as silicon oxide (SiOₓ), silicon nitride (SiNₓ), or silicon oxynitride (SiOₓN_{y}), but aspects of the present disclosure are not limited thereto. The third insulating layer 224) may have a single-layer or multilayer structure.

A planarization layer 241 may be disposed on the third insulating layer 224. The planarization layer 241 can serve to flatten steps caused by the transistor 230 and various signal lines. The planarization layer 241 may be in the form of an organic layer such as an acrylic resin, an epoxy resin, a phenolic resin, a polyamide resin, or a polyimide resin.

A light emitting element ED may be disposed on the planarization layer 241. The light emitting element ED may include a first electrode PE, an intermediate layer EL, and a second electrode CE. For example, the first electrode PE may be an anode electrode or a pixel electrode, and the second electrode CE may be a cathode electrode or a common electrode. For another example, the first electrode PE may be a cathode electrode or a common electrode, and the second electrode CE may be an anode electrode or a pixel electrode. An area where the first electrode PE, the intermediate layer EL, and the second electrode CE are stacked may be defined as a light emitting area.

The first electrode PE may be formed on the planarization layer 241. The first electrode PE may be electrically connected to the first electrode pattern 233 of the transistor 230 through contact holes of the planarization layer 241 and the third insulating layer 224.

A bank 242 may be disposed on the planarization layer 241. The bank 242 may be formed to cover at least one edge of the first electrode PE on the planarization layer 241 to define the light emitting area. The bank 242 may include an open area OA corresponding to the light emitting area. The bank 242 may be in the form of an organic layer such as an acrylic resin, an epoxy resin, a phenolic resin, a polyamide resin, or a polyimide resin.

The bank 242 may comprise an opaque material. The bank 242 may be a black bank with a high light absorption rate. In this implementation, the bank 332 can absorb light traveling in a direction where adjacent subpixels are located, and thereby, color mixing between subpixels SP can be prevented. Further, the bank 332 can absorb external light incident on the display panel 110, and thereby, can reduce reflectivity and serve to improve reflective visibility.

For example, the black bank may be formed by dispersing a colorant in a transparent insulating resin. For example, the colorant may be selected from a carbon-based pigment, a metal oxide-based pigment, or an organic pigment. For example, the carbon pigment may be selected from carbon black, carbon nanotubes, vantablack, or the like, but aspects of the present disclosure are not limited thereto. For example, the metal oxide pigment may be titanium black (TiNₓO_{y}), or Cu-Mn-Fe-based black pigment, but aspects of the present disclosure are not limited thereto. For example, the organic pigment may be selected from lactam black, perylene black, or aniline black, but aspects of the present disclosure are not limited thereto. In another example, the colorant may be a mixture of two or more pigments or dyes having different colors.

Although not shown in FIG. 2, a spacer may be disposed on the bank 242. The spacer may be in the form of an organic layer such as an acrylic resin, an epoxy resin, a phenolic resin, a polyamide resin, or a polyimide resin.

The intermediate layer EL may be disposed on the first electrode PE. The intermediate layer EL may cover the bank 242 and a portion of the first electrode PE not covered by the bank 242. For example, the intermediate layer EL may be an organic emission layer.

The intermediate layer EL can emit any one of red light, green light, blue light, and white light. The intermediate layer EL may be, for example, a white emission layer emitting white light. The intermediate layer EL may have a tandem structure in which two or more stacks are disposed. Each of the stacks may include a hole transport layer (HTL), at least one emission layer (EML), and an electron transport layer (ETL). In addition, a charge generation layer (CGL) may be disposed between the stacks.

In one or more aspects, the light emitting element ED may be disposed in the display panel 110 in a bottom emission (BE) structure or a top emission (TE) structure. For example, in an example where the light emitting element ED is disposed in the bottom emission (BE) structure, the light emitting element ED may be disposed to emit light in a direction toward the substrate 111, i.e., in a downward direction. In another example, in an example where the light emitting element ED is disposed in the top emission (TE) structure, the light emitting element ED may be disposed to emit light in a direction away from the substrate 111, i.e., in an upward direction.

In the example where the light emitting element ED is disposed in the bottom emission (BE) structure, the first electrode PE may include a transparent or semitransparent conductive material capable of allowing light to be transmitted. For example, the first electrode PE may include a transparent conductive oxide (TCO) selected from the group of indium tin oxide (ITO), indium zinc oxide (IZO), indium tin zinc oxide (ITZO), zinc oxide, and tin oxide, which are capable of allowing light to be transmitted. For example, the first electrode PE may include a semi-transmissive conductive material such as magnesium (Mg), silver (Ag), or an alloy of magnesium (Mg) and silver (Ag).

In the example where the light emitting element ED is disposed in the top emission (TE) structure, the first electrode PE may include a metal material having high reflectivity. For example, the first electrode PE may include a high-reflectivity metal material, such as a stack structure of aluminum and titanium (Ti/Al/Ti), a stack structure of aluminum and ITO (ITO/Al/ITO), a stack structure of silver (Ag) and ITO (ITO/Ag/ITO), a stack structure of molybdenum titanium (MoTi) and ITO (ITO/MoTi/ITO), a stack structure of indium zinc oxide (IZO), MoTi and ITO (IZO/MoTi/ITO), an APC alloy, and a stack structure of an APC alloy and ITO (ITO/APC/ITO). The APC alloy is an alloy of silver (Ag), palladium (Pd), and copper (Cu).

The second electrode CE may be formed on the intermediate layer EL.

In the example where the light emitting element ED is disposed in the bottom emission (BE) structure, the second electrode CE may include a metal material having high reflectivity. For example, the second electrode CE may include a high-reflectivity metal material, such as a stack structure of aluminum and titanium (Ti/Al/Ti), a stack structure of aluminum and ITO (ITO/Al/ITO), a stack structure of silver (Ag) and ITO (ITO/Ag/ITO), a stack structure of molybdenum titanium (MoTi) and ITO (ITO/MoTi/ITO), a stack structure of indium zinc oxide (IZO), MoTi and ITO (IZO/MoTi/ITO), an APC alloy, and a stack structure of an APC alloy and ITO (ITO/APC/ITO).

In the example where the light emitting element ED is disposed in the top emission (TE) structure, the second electrode CE may include a transparent or semitransparent conductive material capable of allowing light to be transmitted. For example, the second electrode CE may include a transparent conductive oxide (TCO) selected from the group of indium tin oxide (ITO), indium zinc oxide (IZO), indium tin zinc oxide (ITZO), zinc oxide, and tin oxide, which are capable of allowing light to be transmitted. For example, the second electrode CE may include a semi-transmissive conductive material such as magnesium (Mg), silver (Ag), or an alloy of magnesium (Mg) and silver (Ag).

Hereinafter, for convenience of description, discussions are provided based on an example where the light emitting element ED is disposed in the bottom emission (BE) structure.

An encapsulation layer 250 may be disposed on the second electrode CE.

The encapsulation layer 250 may be disposed to surround the light emitting element ED. For example, the encapsulation layer 250 may have a multilayer structure in which organic material layers and inorganic material layers are alternately stacked. The inorganic material layer can serve to block oxygen or moisture from penetrating into the light emitting element ED. The organic material layer may be disposed to have a thickness relatively greater than the inorganic material layer to sufficiently cover undesired substances (particles) that may be generated during the manufacturing process.

For example, the encapsulation layer 250 may include a first encapsulation layer 251 surrounding the light emitting element ED, a second encapsulation layer 252 surrounding the first encapsulation layer 251, and a third encapsulation layer 253 surrounding the second encapsulation layer 252. Each of the first and third encapsulation layers (251 and 253) may include an inorganic insulating material such as silicon oxide (SiOₓ), silicon nitride (SiNₓ), silicon oxynitride (SiON), or aluminum oxide (AlₓO_{y}). The second encapsulating layer 252 may include at least one organic insulating material selected from the group of, acrylic resin, epoxy resin, phenolic resin, polyamide resin, polyimide resin, benzocyclobutene resin, and fluororesin, but aspects of the present disclosure are not limited thereto.

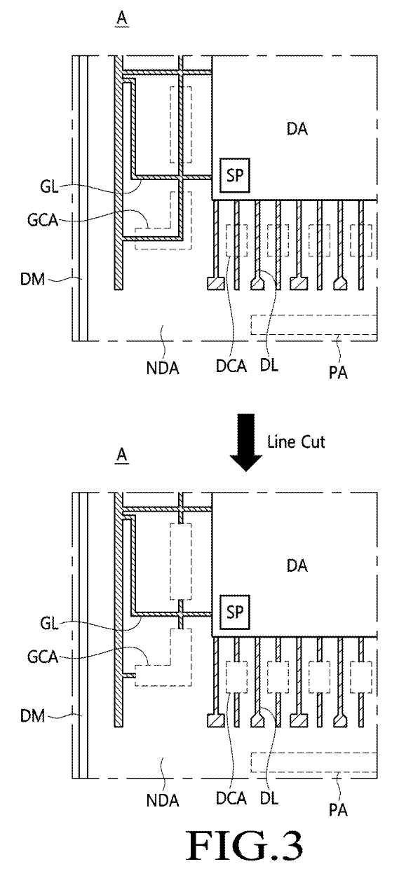

FIG. 3 is an example of an enlarged view of area A of FIG. 1. In discussions that follow for the configuration of FIG. 3, discussions for features and configurations equal, substantially equal, or similar to the features and configurations described with reference to FIGS. 1 and 2 are omitted or briefly described for simplicity.

FIG. 3 illustrates situations after inspecting various power lines and signal lines in the manufacturing process.

An inspection of the appearance of several power lines and signal lines may be desired in the manufacturing process to improve reliability of the quality of the display panel 110 or the display device 100. This appearance inspection may be performed in a visual manner. However, since it is not easy to evaluate accurately in the visual manner whether the metal patterns are opened or shorted, an automatic appearance inspection device (AOI) may be used that can optically recognize the metal patterns and perform inspection by comparing the recognized result with a standard pattern serving as an inspection reference. However, since the automatic appearance inspection device (AOI) may not fully inspect a complex structure, a line-open-short (LOS) inspection may be performed to inspect more accurately whether the metal patterns are opened or shorted.

Referring to FIG. 3, one or more first lines such as data lines DL and the like may be disposed in a first direction on the substrate 111, and one or more second lines such as gate lines GL and the like may be disposed in a second direction. The first lines and the second lines may be disposed on different layers.

Referring to FIG. 3, one or more first line disconnection areas DCA in which a corresponding portion of the one or more first lines is removed and one or more second line disconnection areas GCA in which a corresponding portion of the one or more second line is removed may be disposed in the non-display area NDA. For example, the non-display area NDA may include a first non-display area located at a lower edge of the display panel 110 and a second non-display area located at a left edge of the display panel 110. A pad area PA may be disposed in the first non-display area. A dam structure DM may be disposed in the second non-display area. FIG. 3 illustrates that the dam structure DM is disposed in the second non-display area, but aspects of the present disclosure are not limited thereto. The dam structure DM may be disposed outside of the display panel 110 along the non-display area NDA of the display panel 110. For example, at least one dam structure DM may be disposed in at least one non-display area among the first to fourth non-display areas.

The one or more first line disconnection areas DCA may be located in the first non-display area. For example, the one or more first line disconnection areas DCA may be disposed between an outermost subpixel SP disposed on an outer edge of the display area DA and the pad area PA.

The one or more second line disconnection areas GCA may be disposed in a non-display area excluding the first non-display area. For example, the one or more second line disconnection areas GCA may be located in at least one of the second non-display area, the third non-display area, and the fourth non-display area. The one or more second line disconnection areas GCA may be located between the outermost subpixel SP and the dam structure DM.

A block may be formed to which respective edges of first lines, such as data line DLs and the like, extending to the non-display area NDA are connected. In this configuration, the LOS inspection may be performed to check whether the one or more first lines are opened or shorted. For example, the LOS inspection may be performed to inspect an open defect of each of lines disposed on the substrate 111 or a short defect between the lines.

In addition, in the case of second lines, such as gate lines GL and the like, after the second lines are formed to have equal potential to prevent damage caused by static electricity generated during the manufacturing process, a subsequent process may be performed.

According to this configuration, after the LOS inspection and/or the subsequent process are performed for the first lines and the second lines, a first line disconnection process and a second line disconnection process may be performed. Thereby, respective portions of the first lines and the second lines may be removed in the non-display area NDA.

The first line disconnection process and the second line disconnection process are separate processes. For example, the second line disconnection process may be performed after the first line disconnection process and the subsequent process have been performed. However, the first line disconnection process for removing the portions of the first lines may be performed simultaneously with a wet etching process for patterning the second lines. In this case, etching time may increase to etch the first lines disposed in the first line disconnection area DCA, and thereby, the second line may be over-etched due to the increased etching time.

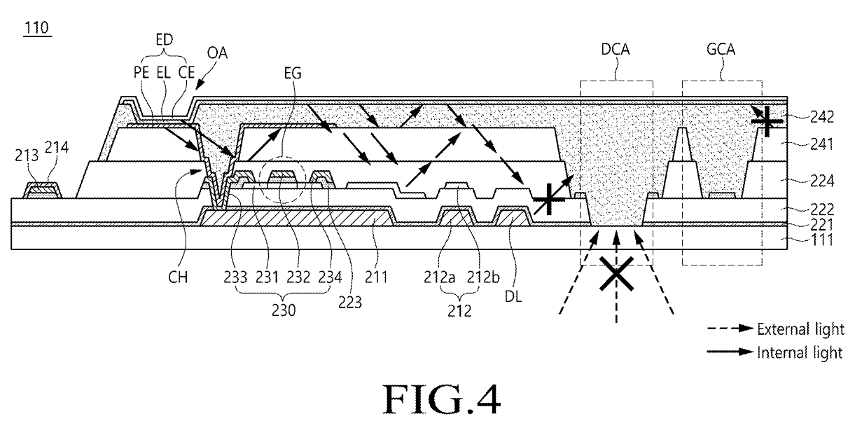

FIG. 4 is an example of a cross-sectional view of the display panel 110 according to aspects of the present disclosure. In discussions that follow for the configuration of FIG. 4, discussions for features and configurations equal, substantially equal, or similar to the features and configurations described with reference to FIGS. 1 to 3 are omitted or briefly described for conciseness.

Referring to FIG. 4, in one or more example embodiments, the display panel 110 may include the substrate 111, the light shielding layer 211 disposed on the substrate 111, a first line such as a data line DL and the like, the first insulating layer 222 disposed on the first line, a thin film transistor 230 disposed on the first insulating layer 222 and including an active layer 231, a gate electrode 232, a first electrode pattern 233, and a second electrode pattern 234, the third insulating layer 224 disposed on the thin film transistor 230, the planarization layer 241 disposed on the third insulating layer 224, and a light emitting element ED disposed on the planarization layer 241.

Referring to FIG. 4, in one or more aspects, the display panel 110 may include a first line disconnection area DCA and a second line disconnection area GCA.

In one or more aspects, one or more first lines among first lines, such as data lines DL and the like, may not be disposed in one or more first line disconnection areas DCA. In one embodiment, a first line may be disconnected into a first portion and a second portion, where the second portion is electrically isolated and is configured as an island structure after the first line disconnection areas DCA have been formed. For example, the first line disconnection area DCA may include the substrate 110, and a bank 242 on the substrate 110. For example, in the first line disconnection area DCA, the substrate 110 may be disposed to directly contact the bank 242. In one embodiment, a vertical thickness of the bank 242 in the first line disconnection area DCA is greater than a vertical thickness of the bank 242 above another first line.

In one or more aspects, one or more second lines, such as gate lines GL and the like, may not be disposed in one or more second line disconnection areas GCA. For example, the second line disconnection area GCA may include the substrate 110, the first insulating layer 222 on the substrate 110, a portion of the second insulating layer 223 on the first insulating layer 222, and the bank 232 on the first insulating layer 222 and the second insulating layer 223. For example, in the second line disconnection area GCA, the substrate 110 may be disposed not to directly contact the bank 242.

Referring to FIG. 4, the bank 232 in the display panel 110 may be a black bank with a high light absorption rate.

Referring to FIG. 4, internal light emitted from the light emitting element ED can be reflected at interfaces of a plurality of layers disposed in the display panel 110. However, the internal light can be absorbed by the bank 242 disposed in the first line disconnection area DCA, and cannot therefore exit the display panel 110. In addition, external light can be absorbed by the bank 242 disposed in the first line disconnection area DCA, and be therefore prevented from entering the inside of the display panel 110. According to these configurations, in the first line disconnection area DCA, internal light and external light each can be absorbed by the bank 242, and thereby, the display panel 110 can provide advantages of increasing a light shielding rate and serving to improve visibility.

In this structure, the first line disconnection area DCA disposed in the display panel 110 can increase the light shielding rate based on an optical density and an increased thickness by the bank 242. Therefore, the display panel 110 can provide an improved visibility.

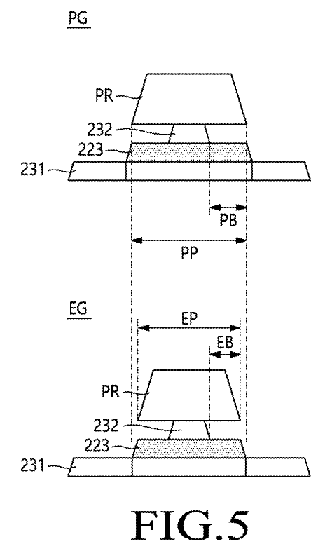

FIG. 5 illustrates respective cross-sections of a normal gate electrode structure PG and a gate electrode structure EG in FIG. 4. In discussions that follow for the configuration of FIG. 5, discussions for features and configurations equal, substantially equal, or similar to the features and configurations described with reference to FIGS. 1 to 4 are omitted or briefly described for conciseness.

FIG. 5 illustrates a schematic cross-sectional view of a normal gate electrode structure PG and a gate electrode structure EG in the display panel 110 according to example embodiments of the present disclosure.

When a metal pattern is formed by wet etching a metal layer, the metal layer located under a photoresist may etched by an etchant, and thereby have an etch bias.

For example, as a line is etched, a gate electrode 232 may be over-etched. Therefore, in the normal gate electrode structure PG, when the gate electrode 232 is over-etched, the etch bias PB of the gate electrode 232 located under the photoresist PR may increase. When the etch bias PB increases, the resolution of a pattern based on a width PP of the photoresist PR may decrease.

In the display panel 110 according to the example embodiments of the present disclosure, other lines (e.g., the remaining lines) except for those disposed in the first line disconnection area DCA and the second line disconnection area GCA can be protected by insulating layers. Therefore, these lines may not be additionally etched. Accordingly, in the gate electrode structure EG according to the example embodiments of the present disclosure, as the gate electrode 232 is not additionally etched, the etch bias EB of the gate electrode 232 located under the photoresist PR can be also reduced. When the etch bias EB is reduced, the resolution of a pattern based on a width EP of the photoresist PR can also be increased. Since the over-etching of second lines can be prevented, a distance between the second lines can be reduced, and thereby, the display device 100 can provide an advantage of presenting a high resolution.

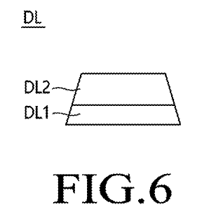

FIG. 6 is an example cross-sectional view of the data line in FIG. 4. In discussions that follow for the configuration of FIG. 6, discussions for features and configurations equal, substantially equal, or similar to the features and configurations described with reference to FIGS. 1 to 5 are omitted or briefly described for conciseness.

In one or more example embodiments, the first line included in the display panel 110 may include any one of a data line DL, a low voltage line VSSL, and a high voltage line VDDL.

Referring to FIG. 6, the first line, such as the data line DL and the like, may have a multilayer structure including two layers. For example, the first line may include a first layer DL1 and a second layer DL2 disposed on the first layer DL1. The first line may include the first layer DL1 including a low-reflective oxide, and the second layer DL2 disposed on the first layer DL1 and including a low-resistivity metal.

The first layer DL1 may include a low-reflective material. The first layer DL1 may include the low-reflective oxide. For example, the first layer DL1 may include a material selected from molybdenum-titanium oxide (MoTiOₓ), molybdenum-tantalum oxide (MoTaOₓ), tungsten oxide (WOₓ), molybdenum-copper oxide (MoCuOₓ), and molybdenum-chromium oxide (MoCrOₓ).

The second layer DL2 may include a low-resistance metal. The second layer DL2 may include a metal having low surface resistance. For example, the second layer DL2 may include a material selected from copper (Cu), aluminum (Al), molybdenum (Mo), titanium (Ti), and an alloy material thereof (e.g., MoTi).

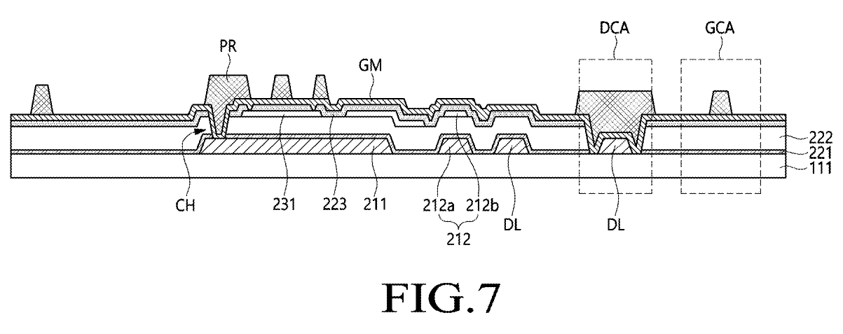

FIGS. 7 to 14 illustrate an example process for manufacturing the display panel 110 according to aspects of the present disclosure. In discussions that follow for the configuration of FIGS. 7 to 14, discussions for features and configurations equal, substantially equal, or similar to the features and configurations described with reference to FIGS. 1 to 6 are omitted or briefly described for conciseness.

Referring to FIG. 7, in one or more example embodiments, a light shielding layer 211, a first insulating layer 222, an active layer 231, a second insulating layer 223, and a gate material layer GM may be sequentially deposited on a substrate 111.

For example, a light shielding material layer may be patterned on the substrate 111 to form a first line such as a data line DL and the like, a light shielding layer 211, and a first capacitor electrode 212a.

The first insulating layer 222 may be formed to cover the first line such as a data line DL and the like, the light shielding layer 211, and the first capacitor electrode 212a. In this case, the first insulating layer 222 may not be formed on a portion of the first line such as a data line DL and the like disposed in the non-display area, and thereby, a first line disconnection area DCA may be formed.

For example, a fourth insulating layer 221 may be formed before the first insulating layer 222 is formed. In the example where the fourth insulating layer 221 is formed, the fourth insulating layer 221 may not be formed in the first line disconnection area DCA.

An active material layer may be patterned on the first insulating layer 222, and thereby, the active layer 231, a second capacitor electrode 212b, and the like may be formed.

The second insulating layer 223 may be patterned and formed on the first insulating layer 222. In this case, the second insulating layer 223 may be disposed to cover the active layer 231 and the second capacitor electrode 212b. For example, the second insulating layer 223 may not be formed in the first line disconnection area DCA.

The gate material layer GM may be formed on the second insulating layer 223. The gate material layer GM may also be formed on the first line such that the gate material layer GM contacts a portion of the first line such as a data line DL and the like in the first line disconnection area DCA. For example, the gate material layer GM may be connected to both ends of the active layer 231 through contact holes formed in the second insulating layer 223, and may be connected to the light shielding layer 211 through contact holes CH formed in the first insulating layer 222 and the second insulating layer 223.

A photoresist PR may be formed in an area corresponding to a pad electrode, a gate electrode, first and second electrode patterns, and the first line disconnection area DCA. In this case, the photoresist PR may be formed in a portion of the gate material layer GM disposed in the non-display area, and thereby, the second line disconnection area GCA may be formed.

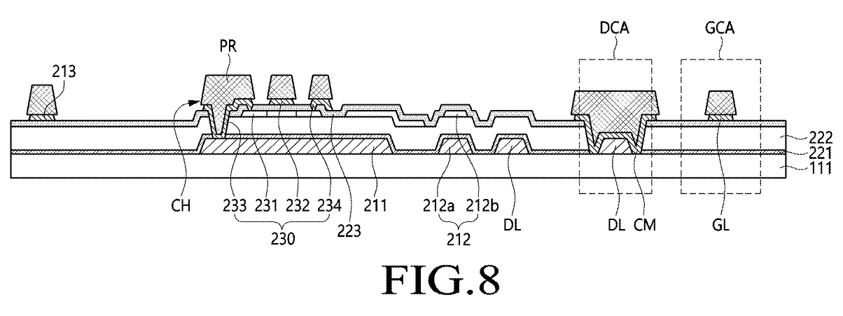

Next, referring to FIG. 8, the gate material layer GM may be etched to form the pad electrode 213, the gate electrode 232, the first and second electrode patterns (233 and 234), and a second line such as a gate line GL and the like. For example, a cover material layer CM covering the first line such as a data line DL and the like may be formed in the first line disconnection area DCA. The gate material layer GM may be patterned through a wet etching process.

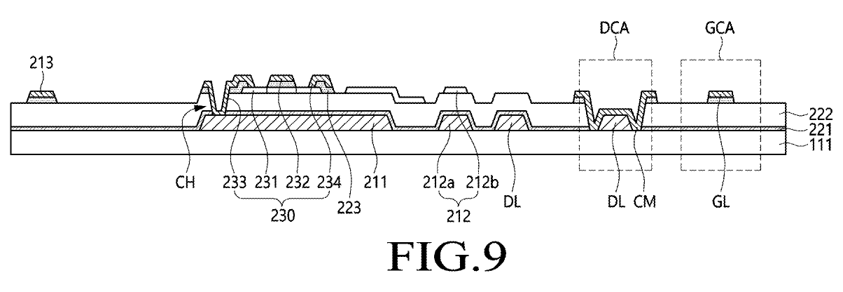

Next, referring to FIG. 9, after the second insulating layer 223 is etched and patterned, the photoresist PR may be removed.

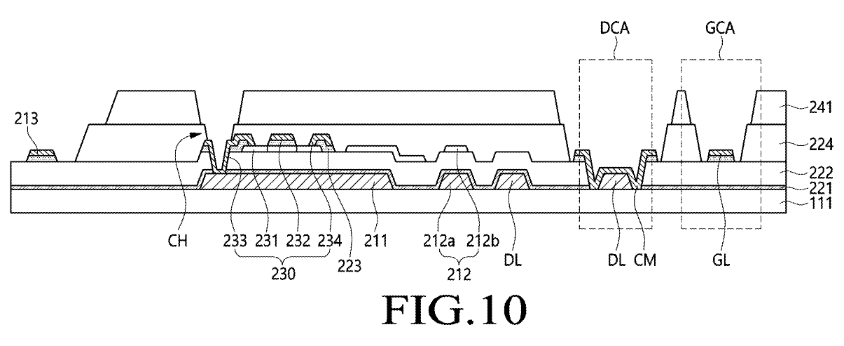

Next, referring to FIG. 10, a third insulating layer 224 may be patterned and formed on the transistor 230. The third insulating layer 224 may be disposed such that a pad part where the pad electrode 213 is disposed, a contact hole CH where the first electrode pattern 233 of the transistor 230 and the light shielding layer 211 are connected, the first line disconnection area DCA, and the second line disconnection area GCA are open.

A planarization layer 241 may be patterned and formed on the third insulating layer 224.

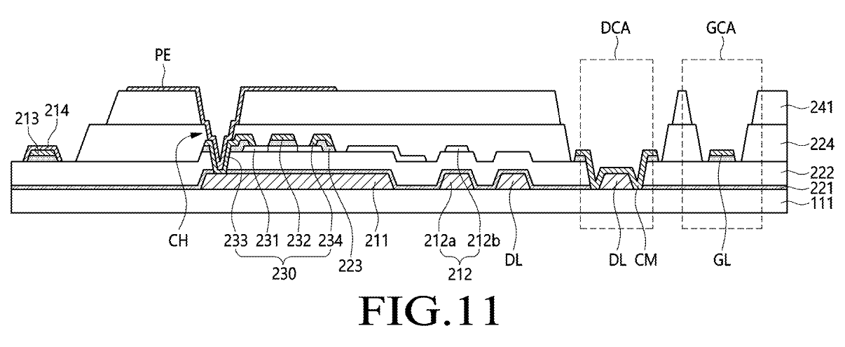

Next, referring to FIG. 11, a first electrode material may be patterned on the planarization layer 241 to form a first electrode PE. The first electrode PE may be electrically connected to the first electrode pattern 233 of the transistor 230 through the contact hole CH formed on the third insulating layer 224 and the planarization layer 241. A pad electrode capping layer 214 may be formed on the pad electrode 213 of the pad part.

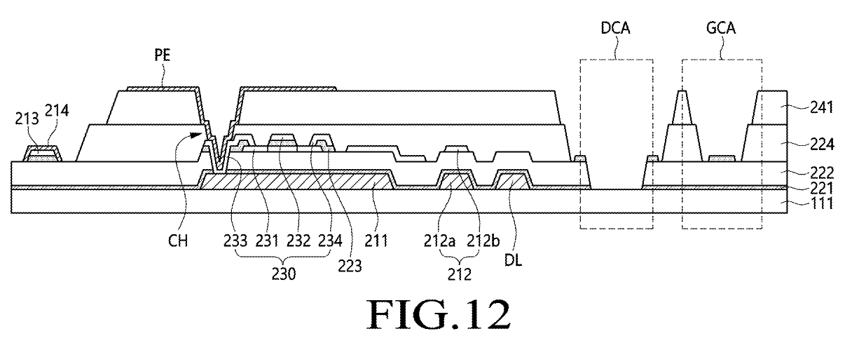

Next, referring to FIG. 12, lines formed in the first line disconnection area DCA and the second line disconnection area GCA may be simultaneously etched and removed by a wet etching process. For example, the first line such as a data line DL and the like disposed in the first line disconnection area DCA and the second line disconnection area GCA, the cover material layer CM formed on the first line, and the second line such as a gate line GL and the like may be simultaneously removed by an etchant.

In this case, other lines except for the lines disposed in the first line disconnection area DCA and the second line disconnection area GCA can be protected by the first insulating layer 222 or the third insulating layer 224 and thus not be additionally etched.

In particular, when the first line includes a low-reflective oxide, a residual film may occur in the wet etching process, which may increase etching time. However, as described above, other lines except for the lines disposed in the first line disconnection area DCA and the second line disconnection area GCA are protected by insulating layers, and thus cannot be additionally etched.

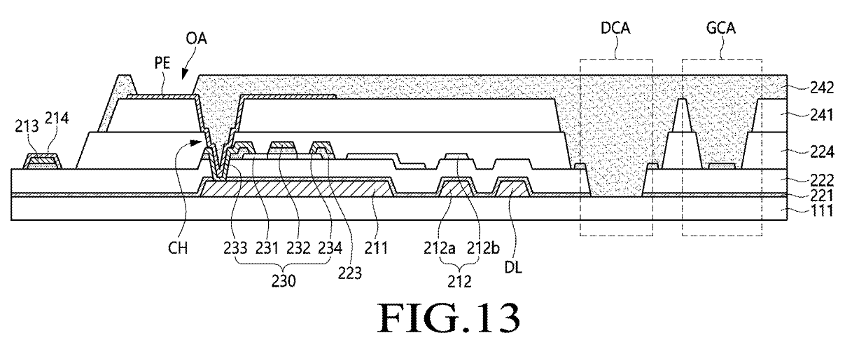

Next, referring to FIG. 13, a bank 242 may be formed to expose at least a portion of the first electrode PE. The portion of the first electrode PE exposed by the bank 242 may correspond to an open area OA of the bank 242. In this case, the bank 242 may be a black bank. The bank 242 may be formed to directly contact the substrate 111 in the first line disconnection area DCA. The bank 242 may be formed to directly contact the first insulating layer 222 in the second line disconnection area GGA.

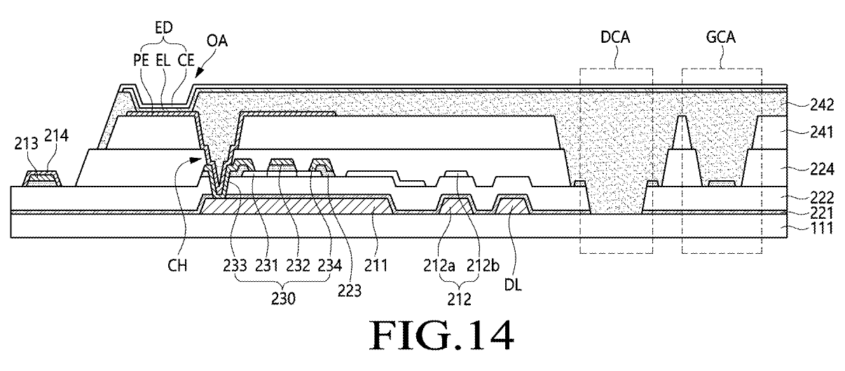

Next, referring to FIG. 14, an intermediate layer EL may be formed by depositing an intermediate layer EL organic material on the first electrode PE and the bank 242. A second electrode CE may be formed by depositing a second electrode PE metal layer on the intermediate layer EL.

Using the example processes of FIGS. 7 to 14, lines disposed in the first line disconnection area DCA and the second line disconnection area GCA may be etched simultaneously. In this case, other lines except for the lines disposed in the first line disconnection area DCA and the second line disconnection area GCA can be protected by insulating layers and therefore not be additionally etched.

The examples, aspects, and embodiments for the display device 100 and the display panel 110 described herein may be described as follows.

According to the one or more example embodiments described herein, a display device can be provided that includes a substrate including a display area including subpixels and a non-display area surrounding the display area, a first line disposed on the substrate and extending in a first direction, a planarization layer disposed on the first line, a light emitting element including a first electrode disposed on the planarization layer, an intermediate layer disposed on the first electrode, and a second electrode disposed on the intermediate layer, a bank including an open area for exposing at least a portion of the first electrode, and a first line disconnection area located in the non-display area, a portion of the first line being disconnected in the first line disconnection area. In one or more aspects, the substrate and the bank may be disposed to contact each other in the first line disconnection area.

In one or more aspects, in the display device, the bank may comprise an opaque material.

In one or more aspects, in the display device, the bank may be a black bank.

In one or more aspects, in the display device, the first line may be any one of a data line, a low voltage line, and a high voltage line.

In one or more aspects, in the display device, the first line may include a first layer including a low-reflective oxide, and a second layer disposed on the first layer and including a low-resistance metal.

In one or more aspects, in the display device, the first layer may include a material selected from molybdenum-titanium oxide (MoTiOₓ), molybdenum-tantalum oxide (MoTaOₓ), tungsten oxide (WOₓ), molybdenum-copper oxide (MoCuOₓ), and molybdenum-chromium oxide (MoCrOₓ). In one or more aspects, the second layer may include a material selected from copper (Cu), aluminum (Al), molybdenum (Mo), titanium (Ti), and an alloy thereof.

In one or more aspects, the display device may further include a first insulating layer disposed to cover the first line, a transistor disposed on the first insulating layer, and comprising an active layer, a gate electrode, a first electrode pattern, and a second electrode pattern, a second line disposed on the same layer as the gate electrode, and a second line disconnection area located in the non-display area, a portion of the second line being disconnected in the second line disconnection area. In one or more aspects, the first insulating layer and the bank may contact each other in the second line disconnection area.

In one or more aspects, the display device may further include a light shielding layer disposed to be overlapped with at least a portion of the active layer. In one or more aspects, the light shielding layer may be located between the substrate and the first insulating layer.

In one or more aspects, in the display device, the first electrode pattern of the transistor may be electrically connected to the light shielding layer through a contact hole of the first insulating layer.

In one or more aspects, in the display device, the light shielding layer and the first line may be disposed in the same layer.

In one or more aspects, the display device may further include a third insulating layer disposed on the transistor. In one or more aspects, the first electrode of the light emitting element may be electrically connected to the first electrode pattern of the transistor through contact holes of the third insulating layer and the planarizing layer.

In one or more aspects, in the display device, the non-display area may include a first non-display area located outside of the display area in a first direction, a second non-display area located outside of the display area in a second direction perpendicular to the first direction, a third non-display area located outside of the display area in a direction opposite to the first direction, and a fourth non-display area located outside of the display area in a direction opposite to the second direction. In one or more aspects, the first line disconnection area may be located in the first non-display area. In one or more aspects, the second line disconnection area may be located in at least one of the second non-display area to the fourth non-display area.

In one or more aspects, in the display device, the first non-display area may include a pad area, and the first line disconnection area may be disposed between an outermost subpixel disposed at an outer edge of the display area and the pad area.

In one or more aspects, in the display device, the second to fourth non-display areas may include at least one dam structure, and the second line disconnection area may be disposed between the outermost subpixel disposed at the outer edge of the display area and the dam structure.

According to the one or more aspects described herein, a display device may be provided that is capable of improving a light shielding ratio by including a structure where a black bank is disposed to contact a substrate.

According to the one or more aspects described herein, a display device may be provided that is capable of improving visibility by including a structure where internal and external light is blocked in a non-display area.

According to the one or more aspects described herein, a display device may be provided that is capable of presenting a high resolution by including a structure where over-etching of metal layers can be prevented and a distance between lines can be minimized.

According to the one or more aspects described herein, a display device may be provided that is capable of enabling process optimization by including a structure where metal layers located in different layers are simultaneously removed.

According to the one or more aspects described herein, a display device may be provided that is capable of presenting a high resolution and being driven with low power by including a structure where a distance between lines can be minimized.

According to the one or more aspects described herein, a display device may be provided that comprises a substrate comprising a display area comprising subpixels and a non-display area, a first line disposed on the substrate and extending in a first direction, an insulating layer disposed on the first line, a light emitting element comprising a first electrode disposed on the insulating layer, an intermediate layer disposed on the first electrode, and a second electrode disposed on the intermediate layer, a bank comprising an open area for exposing at least a portion of the first electrode, and a first line disconnection area located in the non-display area. In one or more aspects, in the display device, a first portion of the first line is disconnected from a second portion of the first line in the first line disconnection area. In one or more aspects, in the display device, a vertical thickness of the bank located in the first line disconnection area is greater than a vertical thickness of the bank located above an another first line.

In one or more aspects, in the display device, the substrate and the bank may contact each other in the first line disconnection area.

In one or more aspects, the bank may be a black bank.

In one or more aspects, in the display device, the each of the first line and the another first line may be selected from a data line, a low voltage line, and a high voltage line.

In one or more aspects, in the display device, the second portion of the first line may be electrically isolated.

In one or more aspects, the display device may further comprise a second line disconnection area located in the non-display area, a portion of the second line being disconnected in the second line disconnection area. In one or more aspects, the first line disconnection area and the second line disconnection area may beconfigured such that light is blocked in the non-display area.

In one or more aspects, the substrate and the bank may do not contact each other in the second line disconnection area.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the principles described herein may be applied to other embodiments and applications without departing from the scope of the present disclosure. The above description and the accompanying drawings provide an example of the technical idea of the present disclosure for illustrative purposes only. That is, the disclosed embodiments are intended to illustrate the scope of the technical idea of the present disclosure.

What is claimed is:

1. A display device comprising:
a substrate comprising a display area comprising subpixels and a non-display area surrounding the display area;
a first line disposed on the substrate and extending in a first direction;
a planarization layer disposed on the first line;
a light emitting element comprising a first electrode disposed on the planarization layer, an intermediate layer disposed on the first electrode, and a second electrode disposed on the intermediate layer;
a bank comprising an open area for exposing at least a portion of the first electrode; and
a first line disconnection area located in the non-display area, a portion of the first line being disconnected in the first line disconnection area,
wherein the substrate and the bank contact each other in the first line disconnection area.

2. The display device of claim 1, wherein the bank comprises opaque material.

3. The display device of claim 1, wherein the bank is a black bank.

4. The display device of claim 1, wherein the first line is selected from a data line, a low voltage line, and a high voltage line.

5. The display device of claim 1, wherein the first line comprises:
a first layer comprising a low-reflective oxide; and
a second layer disposed on the first layer and comprising a low-resistance metal.

6. The display device of claim 5, wherein the first layer comprises a material selected from molybdenum-titanium oxide (MoTiOₓ), molybdenum-tantalum oxide (MoTaOₓ), tungsten oxide (WOₓ), molybdenum-copper oxide (MoCuOₓ), and molybdenum-chromium oxide (MoCrOₓ), and the second layer comprises a material selected from copper (Cu), aluminum (Al), molybdenum (Mo), titanium (Ti), and an alloy thereof.

7. The display device of claim 1, further comprising:
a first insulating layer disposed to cover the first line;
a transistor disposed on the first insulating layer, and comprising an active layer, a gate electrode, a first electrode pattern, and a second electrode pattern;
a second line disposed on the same layer as the gate electrode; and
a second line disconnection area located in the non-display area, a portion of the second line being disconnected in the second line disconnection area,
wherein the first insulating layer and the bank contact each other in the second line disconnection area.

8. The display device of claim 7, further comprising a light shielding layer disposed to be overlapped with at least a portion of the active layer,
wherein the light shielding layer is located between the substrate and the first insulating layer.

9. The display device of claim 8, wherein the first electrode pattern of the transistor is electrically connected to the light shielding layer through a contact hole of the first insulating layer.

10. The display device of claim 9, wherein the light shielding layer and the first line are disposed in a same layer.

11. The display device of claim 7, further comprising a third insulating layer disposed on the transistor,
wherein the first electrode of the light emitting element is electrically connected to the first electrode pattern of the transistor through contact holes of the third insulating layer and the planarizing layer.

12. The display device of claim 7, wherein the non-display area comprises:
a first non-display area located outside of the display area in a first direction;
a second non-display area located outside of the display area in a second direction perpendicular to the first direction;
a third non-display area located outside of the display area in a direction opposite to the first direction; and
a fourth non-display area located outside of the display area in a direction opposite to the second direction,
wherein the first line disconnection area is located in the first non-display area, and the second line disconnection area is located in at least one of the second non-display area to the fourth non-display area.

13. The display device of claim 12, wherein the first non-display area comprises a pad area, and wherein the first line disconnection area is disposed between an outermost subpixel disposed at an outer edge of the display area and the pad area; and/or
wherein the second to fourth non-display areas comprise at least one dam structure, and the second line disconnection area is disposed between the outermost subpixel disposed at the outer edge of the display area and the at least one dam structure.

14. A display device comprising:
a substrate comprising a display area comprising subpixels and a non-display area;
a first line disposed on the substrate and extending in a first direction;
an insulating layer disposed on the first line;
a light emitting element comprising a first electrode disposed on the insulating layer, an intermediate layer disposed on the first electrode, and a second electrode disposed on the intermediate layer;
a bank comprising an open area for exposing at least a portion of the first electrode; and
a first line disconnection area located in the non-display area, wherein a first portion of the first line is disconnected from a second portion of the first line in the first line disconnection area;
wherein a vertical thickness of the bank located in the first line disconnection area is greater than a vertical thickness of the bank located above an another first line.

15. The display device of claim 14, wherein the substrate and the bank contact each other in the first line disconnection area.

16. The display device of claim 14, wherein the bank is a black bank.

17. The display device of claim 14, wherein each of the first line and the another first line is selected from a data line, a low voltage line, and a high voltage line.

18. The display device of claim 14, wherein the second portion of the first line is electrically isolated.

19. The display device of claim 14, further comprising a second line disconnection area located in the non-display area, a portion of the second line being disconnected in the second line disconnection area, wherein the first line disconnection area and the second line disconnection area are configured such that light is blocked in the non-display area.

20. The display device of claim 19, wherein the substrate and the bank do not contact each other in the second line disconnection area.
